(19) United States
(12) Patent Application Publication
(10) Pub. No.: US 2011/0132773 A1
(43) Pub. Date: Jun. 9, 2011

(54) APPARATUS AND METHOD FOR DETECTING SUBSTANCES

(76) Inventors: Dirk Liemersdorf, Gerlingen (DE); Richard Fix, Gerlingen (DE); Oliver Wolst, Nuertingen (DE); Alexander Martin, Ludwigsburg (DE); Martin Le-Huu, Korntal (DE)

(21) Appl. No.: 12/452,673

(22) PCT Filed: Jul. 3, 2008
(86) PCT No.: PCT/EP2008/058571

§ 371 Date: Jun. 21, 2010

(30) Foreign Application Priority Data
Jul. 24, 2007 (DE) 10 2007 034 330.4

(51) Int. Cl. G01N 27/414; H01L 29/772

(52) U.S. Cl. 205/775; 257/253; 257/E29.242

(57) ABSTRACT

An apparatus for detecting at least one substance present in a fluid flow includes at least one field effect transistor which acts as a measuring sensor, and at least one field effect transistor which acts as a reference element, the field effect transistors each having at least one source electrode, one drain electrode, and one gate electrode. The gate electrode of the field effect transistor which acts as the measuring sensor is sensitive to the at least one substance to be detected, and the gate electrode of the field effect transistor which acts as the reference element is essentially insensitive to the at least one substance to be detected. The source electrode of one of the field effect transistors and the drain electrode of the other of the field effect transistors are connected to one another and to a signal line. A method for detecting at least one substance present in a fluid flow by using the apparatus is also described, a potential of 0 volt being applied to the signal line and the current flowing on the signal line being measured.

### FIELD OF THE INVENTION

The present invention is directed to an apparatus for detecting at least one substance contained in a fluid flow. In addition, the present invention is directed to a method for detecting at least one substance contained in a fluid flow by using the apparatus.

### BACKGROUND INFORMATION

Gas-sensitive field effect transistors based on semiconductors are used for detecting substances contained in a fluid flow, in particular gases in a gas stream. In general, exposure to the substance to be detected, e.g., a gas or a liquid and/or a gas or liquid mixture, results in a change in the channel impedance and thus a change in the current, the so-called channel current, flowing from the source electrode to the drain electrode through the field effect transistor. If using semiconductor materials having a large band gap of greater than 3 eV, e.g., gallium nitride or silicon carbide, in principle this allows the use of gas-sensitive field effect transistors for sensor applications at temperatures up to 800° C.

At the selected operating point of the gas-sensitive field effect transistor, in the absence of exposure to the substance to be detected, the channel current, the so-called zero signal or the offset, is often higher than the change in the channel current (signal) due to the exposure by a few orders of magnitude, usually 10³. This makes high demands on the current measurement because of the poor signal-offset ratio.

Furthermore, the problem also occurs that the offset is subject to influence by external interfering factors. The external interfering factors arise, e.g., due to changes in temperature or sensor degradation, which are not based on the presence of substances to be detected. Because of the given signal-offset ratio, the change in the channel current due to sensor influences may be of the same order of magnitude or, in the worst case, even greater than the change which occurs due to the presence of the substance to be detected. The associated error in the measuring signal is large because it is impossible to completely rule out all interfering factors, and in the worst case, a usable measurement of the substance to be detected may be prevented.

It is discussed in U.S. Pat. No. 6,883,364 that field effect transistors may be used in hand-held devices as suitable sensors, among others, for detecting gases. However, gas-sensitive resistors, so-called chemoresistors, are generally used here. A voltage divider and a current limiter are implemented through a reference resistor having minimal temperature drift. However, this circuit is not suitable for drift compensation or for compensating the offset of the chemoresistors.

International Patent Application WO-A 2005/103667 discusses the use of a gas sensor based on a field effect transistor and composed of a gas-sensitive layer and a reference layer, whose changes in work function trigger field effect structures. The reference layer is used to eliminate cross-sensitivities, i.e., a sensitivity to gases other than the desired target gas, but WO-A 2005/103667 does not solve the problem of the offset being greater by several orders of magnitude than the change in channel current, and therefore the change in channel current being no greater than the change due to interfering factors.

### SUMMARY OF THE INVENTION

The apparatus according to the present invention for detecting at least one substance present in a fluid flow includes at least one field effect transistor which acts as a measuring sensor and at least one field effect transistor which acts as a reference element. Each field effect transistor has at least one source electrode, one drain electrode, and one gate electrode. The gate electrode of the field effect transistor, which acts as a measuring transistor, is sensitive to the at least one substance to be detected, and the gate electrode of the field effect transistor, which acts as a reference element, is essentially less sensitive to the at least one substance to be detected. According to the exemplary embodiments and/or exemplary methods of the present invention, the source electrode of one of the field effect transistors and the drain electrode of the other field effect transistor are connected to one another and to a signal line. In addition, a voltage is applied between the drain electrode of the first field effect transistor and the source electrode of the second field effect transistor. The current through the signal line is thus the difference in the channel currents of the two field effect transistors (differential current).

The advantage of the circuit according to the exemplary embodiments and/or exemplary methods of the present invention is that the field effect transistor, which acts as a reference element, experiences the same interfering effects, e.g., temperature fluctuations or pressure fluctuations, as the field effect transistor, which acts as the measuring sensor. First-order compensation of the measuring signal (channel current) of the measuring sensor is possible by a suitable choice of the voltages of the drain electrode of the one field effect transistor, the signal line, the source electrode of the other field effect transistor, and the voltage across the gate electrode of both field effect transistors. In other words, the compensation takes place directly in the sensor by wiring one or more field effect transistors, which are sensitive to the substance to be detected, to one or more field effect transistors which act as a reference element and in particular not only offset but also interfering factors are compensated. This reduces the effect of interference on the measuring signal and achieves a greatly improved signal-to-noise ratio.

In contrast, in zero-order compensation, constant current, adapted to the zero signal of the field effect transistor, acting as a measuring sensor, is subtracted in an electronic evaluation unit. The zero-order compensation is independent of the presence of substances to be detected, but this does not improve the signal-to-noise ratio because the fluctuations in the offset result in faulty compensation due to the interference and thus in the same absolute error in the measuring signal. In the circuit according to the exemplary embodiments and/or exemplary methods of the present invention and the first-order compensation thereby achieved, the signal measurement is simplified and the signal-to-noise ratio is greatly improved because interference has an influence on the measuring signal only in the second order, i.e., the influence of the sensor response to the substances to be detected, but no longer in the first order, i.e., the change in the offset.

The measuring signal of the field effect transistor which acts as a measuring sensor is compensated with respect to unwanted components and/or interfering factors in this way. Unwanted components and/or interfering factors include all influences on the measuring signal which are not caused by the interaction of the substance to be detected with the gate electrode of the field effect transistor, which acts as a measuring sensor. Unwanted components include, for example, the signal offset, the temperature dependence of the signal current and the deviation in the signal current of field effect transistors of the same design because of variations in the manufacture of the transistor. One variable to be compensated is the aging and/or the morphological/structural degradation of the field effect transistor, which acts as a measuring sensor, over the operating period. Cross-sensitivity to the presence of substances which do not belong to the substances to be detected is also unwanted. Compensation also includes a reduction in the proportion of the unwanted components in the measuring signal.

The field effect transistor, which acts as the reference element, and the field effect transistor, which acts as the measuring sensor, may be MOSFETs, MISFETs, MESFETs, HEMTs or suspended-gate FETs. The field effect transistor, which acts as a reference element, and the field effect transistor, which acts as a measuring sensor, may also be any other gas-sensitive embodiment of a field effect transistor. The field effect transistor, which acts as a measuring sensor, may be manufactured from an epitaxially grown material composition of the elements of group III and group V and/or group IV elements, which may be silicon, GaAs, SiC, GaN, AlGaN/GaN or any other semiconductor material that may be used.

In one specific embodiment, the field effect transistor, which acts as a measuring sensor, and the field effect transistor, which acts as a reference element, have the same design. Furthermore, they have the same proportions, the same dimensions and the same doping/doping concentrations as well as doping curves except for the passivation layer of the reference element. In addition, the two field effect transistors may be positioned side by side and/or coupled in a thermally conductive manner. The field effect transistor, which acts as a reference element, ideally has the same behavior as the field effect transistor, which acts as a measuring sensor. The field effect transistor, which acts as a reference element, is ideally insensitive, but in any case is much less sensitive to the substances to be detected than is the field effect transistor which acts as a measuring sensor.

In one specific embodiment, the field effect transistor which acts as a reference element is identical in design to the field effect transistor which acts as a measuring sensor, but it does not respond to the presence of the substances to be detected. The lack of sensitivity according to the exemplary embodiments and/or exemplary methods of the present invention is achieved by additional passivation of the catalytically active gate electrode of the field effect transistor which acts as a reference element. Therefore, the substances to be detected are no longer able to interact with the gate electrode. For passivation, the gate electrode of the field effect transistor which acts as a reference element is coated with a passivation layer of a dielectric and/or gas-impermeable material, which is impermeable with respect to the at least one substance to be detected or acts as a diffusion barrier.

The layer thickness is between 1 nm and 100 μm, for example, and may be in the range between 10 nm and 1 μm. The material may be ceramics as well as organic polymers, which may be silicon nitride, silicon carbide, silicon dioxide, aluminum oxide and/or zirconium oxide or mixtures of these materials. Furthermore, ceramic/ceramic and/or ceramic/polymer composite materials may also be used. Any other material which is suitable for passivation and is known by those skilled in the art may be used. The passivation should have little or no influence on the electric properties of the field effect transistor which acts as a reference element.

The passivation of the gate electrode of the field effect transistor which acts as a reference element is accomplished, e.g., by deposition of the passivation material by using microstructured thin-film methods, which have become established in semiconductor technology, e.g., vapor deposition or sputtering. If necessary, heating steps are performed, supporting dense sintering of the passivation layer. Wet chemical deposition of the passivation material with a subsequent thermal treatment is also possible. The elevated temperature of the thermal treatment results in, firstly, evaporation of the volatile solvent, and secondly results in dense sintering of the deposited passivation material. Possible deposition of the passivation material may also be accomplished in a structuring thick-film method, e.g., by printing a paste containing the passivating agent. Subsequent heating steps support dense sintering of the passivation material.

In another specific embodiment, the passivation layer has multiple layers of material, which may be manufactured either in one deposition step or by repeated application of the passivation material. If the passivation layer has multiple layers of material, then these may be made of different materials or it is also possible to apply multiple passivation layers of the same material.

If the passivation layer on the gate electrode of the field effect transistor which acts as a reference element is not impervious with respect to the substances to be detected but instead acts as a diffusion barrier, having the result that the gate electrode of the field effect transistor which acts as a reference element does not interact with the substances to be detected because they do not reach the actual electrode material.

As an alternative to applying a passivation layer it is also possible that the gate electrode is made from a material which is insensitive to the at least one substance to be detected. This is achieved, for example, by using a different material for the gate electrode and/or adjusted porosities of the gate materials or of the entire gate electrode. The gate electrode is insensitive in particular when it has a sufficiently thick and non-porous plating. When other materials are used for the gate electrode, it may be insensitive to the substances to be detected, but not, however, to other substances contained in the fluid flow.

In one specific embodiment, the source electrode of one of the field effect transistors (hereinafter FET1) and the drain electrode of the other of the field effect transistors (hereinafter FET2) are connected to each other and to a signal line. A constant voltage U₁ is applied between the drain electrode of FET1 and the source electrode of FET2. The electric potential of the signal line is exactly in the middle between the electric potential of the drain electrode of FET1 and the source electrode of FET2. It follows from this that the source-drain voltage of FET1 is the same as the source-drain voltage of FET2, and the voltage U₁ is exactly twice that of one of the source-drain voltages of one of the field effect transistors FET1 or FET2.

In the specific embodiment described here, the same gate voltage U_{G} is applied to both field effect transistors between the source electrode and the gate electrode of the particular field effect transistor. If the field effect transistors are self-conducting transistors, i.e., the semiconductor channel is not pinched off at a gate voltage of 0 volt, then the gate voltage may be 0 volt. In general, however; the gate voltage is different from 0 volt. In the specific embodiment described here, both field effect transistors ideally have the same electric characteristic. Due to the identical gate voltage and the identical source-drain voltage for the two field effect transistors, the same current flows between the source electrode and the drain electrode in both field effect transistors if the field effect transistors are not influenced by the fluid flow (offset current). Consequently, in this specific case, no current flows through the signal line. In the specific embodiment described here, one field effect transistor also acts as a measuring sensor and the other field effect transistor acts as a reference element. If the channel current of the field effect transistor which acts as a measuring sensor is influenced by the presence of substances in the fluid flow, then there is a difference in the channel current between the two field effect transistors.

This differential current flows through the signal line. If the two field effect transistors respond similarly to interfering factors, then there is no difference in the channel current of the two field effect transistors due to interfering factors. In the specific embodiment described here, the current on the signal line is used as a measuring signal. This measuring signal is compensated in the first order with respect to offset and interfering factors, as described previously.

In one specific embodiment, the gate voltage of the field effect transistor which acts as a reference element differs from the gate voltage of the field effect transistor which acts as a measuring sensor to correct a deviation (caused by manufacturing inaccuracies and by the airtight passivation of the gate electrode of the field effect transistor which acts as a reference element) between the field effect transistor which acts as a reference element and the field effect transistor which acts as the measuring sensor. This difference in the gate voltage of the two field effect transistors is referred to below as the compensation voltage. The compensation voltage is adjusted in such a way that under desired external conditions, i.e., temperature, pressure, etc., and in the absence of the substances to be detected, no current flows through the signal line. A measuring signal occurring then is in turn to be attributed to the presence of the substances to be detected or to second-order interferences.

In another variant of the method, instead of using the current through the signal line as the measuring signal, the current on the signal line is kept constant by varying the voltage of the voltage source, which is connected to the gate voltage of the field effect transistor which acts as the reference sensor. The gate voltage of the measuring sensor is kept constant. The change in the gate voltage of the reference element is the measuring signal. In another variant, the gate voltage of/the field effect transistor acting as the measuring signal may also be varied to keep the current on the signal line constant. The gate voltage of the reference element is then kept constant, and the change in the gate voltage of the field effect transistor which acts as a measuring sensor represents the measuring signal.

In an alternative variant of the method, the current on the signal line is kept constant by varying the electric potential of the signal line accordingly. The gate voltages of the two field effect transistors then remain constant. The measuring signal is the change in the electric potential of the signal line which is required to keep the current constant.

Exemplary embodiments of the present invention are illustrated in the drawings and explained in greater detail in the following description.

### BRIEF DESCRIPTION OF THE DRAWINGS

FIG. 1 shows a diagram of an apparatus according to the present invention in a first specific embodiment.

FIG. 2 shows a diagram of an apparatus according to the present invention in a second specific embodiment.

FIG. 3 shows a diagram of an apparatus according to the present invention in a third specific embodiment.

FIG. 4 shows an alternative circuit of the specific embodiment shown in FIG. 1.

FIG. 5 shows an alternative circuit of the specific embodiment shown in FIG. 2.

### DETAILED DESCRIPTION

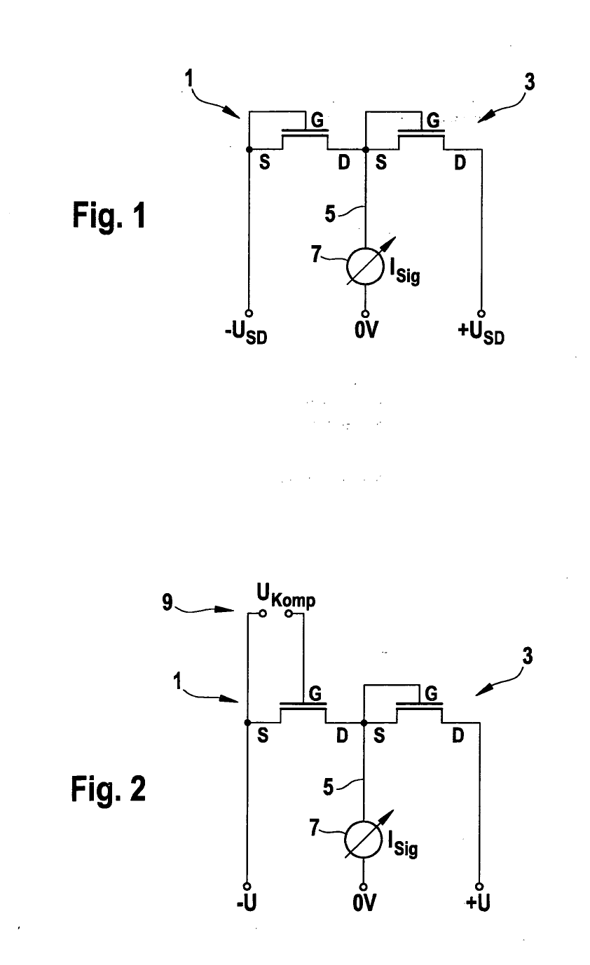

FIG. 1 shows a diagram of an apparatus according to the present invention in a first specific embodiment.

In the specific embodiment shown in FIG. 1, a first field effect transistor 1 and a second field effect transistor 3 are wired together. To do so, source electrode S of second field effect transistor 3 and drain electrode D of first field effect transistor 1 are connected. In addition, drain electrode D of first field effect transistor 1 and source electrode S of second field effect transistor 3 are connected to a signal line 5.

First field effect transistor 1 may be a field effect transistor which acts as a reference element and second field effect transistor 3 is a field effect transistor which acts as a measuring sensor. Gate electrode G of first field effect transistor 1 which acts as a reference element is usually insensitive to a substance to be detected in a fluid flow, as described above. This is accomplished by passivation of gate electrode G, for example.

Detection of the substance to be detected, which is present in a fluid flow, is performed at a source-gate voltage of 0 volt and a constant source-drain voltage U_{SD}. The source-gate voltage of 0 volt is achieved by connecting source electrode S to gate electrode G of second field effect transistor 3 which acts as a measuring sensor. The source-drain voltage is achieved by applying a voltage U_{SD}, which is different from 0 volt, to drain electrode D of second field effect transistor 3.

A voltage of −U_{SD} is applied to source electrode S of first field effect transistor 1 which acts as a reference element. The source-drain voltage of field effect transistor 1 which acts as a reference element is thus exactly equal to the source-drain voltage of second field effect transistor 3 which acts as a measuring sensor. The source-gate voltage of first field effect transistor 1 which acts as a reference element is also 0 volt. As is the case with second field effect transistor 3 which acts as a measuring sensor, this is achieved by connecting the source electrode to the gate electrode.

The signal is measured by measuring the current flowing through signal line 5. To do so, a measuring arrangement or device is provided in signal line 5 for measuring current 7. Any measurement device known to those skilled in the art may be used to measure current 7. This is usually accomplished in the signal evaluation unit.

If second field effect transistor 3 which acts as a measuring sensor and first field effect transistor 1 which acts as a reference element are identical except for their sensitivity to the substances to be detected, then the zero signal current through the channel of second field effect transistor 3 which acts as a measuring sensor corresponds exactly to the channel current of field effect transistor 1 which acts as a reference element. As long as the substance to be detected is not present in the fluid flow, only the zero signal current flows through the channel of second field effect transistor 3 which acts as a measuring sensor. Therefore, according to Kirchhoff's node law, no current flows through signal line 5. If both field effect transistors 1, 3 respond identically to interfering factors, then the current through the signal line will always remain zero, regardless of the external parameters, as long as no substance to be detected is present. In the presence of the substance to be detected, the channel current of second field effect transistor 3 which acts as a measuring sensor changes. However the channel current of first field effect transistor 1 which acts as a reference element does not change. This difference with respect to the zero signal current must flow through signal line 5. Consequently, the current measured in signal line 5 is a function only of the presence of at least one substance to be detected and is compensated with respect to the offset of second field effect transistor 3 which acts as a measuring sensor by the wiring shown in FIG. 1, having first field effect transistor 1 which acts as a reference element and is thus also independent of the change in the offset due to interfering factors such as those which may occur due to changes in temperature or pressure for example.

If first field effect transistor 1 which acts as a reference element has a gate electrode G having a passivation layer, then it may be assumed that a complete correspondence between first field effect transistor 1 and second field effect transistor 3 is not achievable. There is therefore a deviation between the offset current of second field effect transistor 3 which acts as a measuring sensor and the channel current of first field effect transistor 1 which acts as a reference element. This error is also known as compensation error. The deviation also contributes to the current through signal line 5, but is much smaller than the original zero signal. The measuring signal therefore depends only on interfering factors with regard to the compensation error and no longer with regard to the zero signal itself. The measuring signal thus has only a second-order error.

FIG. 2 shows an apparatus designed according to the present invention in a second specific embodiment.

In the specific embodiment illustrated in FIG. 2, the gate electrode of first field effect transistor 1 which acts as a reference element is connected to a potential terminal of a first voltage source 9. At first voltage source 9, an additional compensation voltage U_{Komp} may be applied to the gate electrode of first field effect transistor 1 which acts as a reference element. Through compensation voltage U_{Komp}, it is possible to correct the deviation between the channel voltages of first field effect transistor 1 which acts as a reference element and second field effect transistor 3 which acts as a measuring sensor caused by manufacturing inaccuracies and passivation of the gate electrode of field effect transistor 1 which acts as a reference element. Compensation voltage U_{Komp} is set so that no current flows through signal line 5 under desired external conditions, i.e., temperature, pressure, etc., and in the presence of the at least one substance to be detected. A measuring signal in signal line 5 is then in turn attributable only to the presence of the at least one substance to be detected or to second-order interference.

In addition to the specific embodiment shown in FIG. 2, in which compensation voltage U_{Komp} is applied to gate electrode G of first field effect transistor 1 which acts as a reference element, compensation voltage U_{Komp} may also be applied to gate electrode G of second field effect transistor 3 which acts as a measuring sensor.

In addition to the specific embodiments illustrated in FIGS. 1 and 2 in which at least one field effect transistor 1, 3 is operated at a source-gate voltage of 0 volt, it also possible for second field effect transistor 3 which acts as a measuring sensor to be operated at a source-gate voltage U_{SG} different from zero. To do so, a second voltage source 11 is connected to gate electrode G of second field effect transistor 3. If second field effect transistor 3 which acts as a measuring sensor is operated at a source-gate voltage U_{SG} different from 0 volt, then for complete compensation of the offset, it is also necessary for first field effect transistor 1 which acts as a reference element to be operated at a source-gate voltage U_{SG} different from 0 volt. The source-gate voltage of field effect transistor 1 which acts as a reference element and that of second field effect transistor 3 which acts as a measuring sensor may differ only with regard to an additional compensation voltage U_{Komp} for compensating manufacturing inaccuracies, which may occur due to the passivation of gate electrode G of first field effect resistor 1 which acts as a reference element.

In the alternative circuit shown in FIG. 4 of the specific embodiment shown in FIG. 1, signal detection is based not on a change in the current in signal line 5 but instead on a change in the voltage in signal line 5. Like the specific embodiment shown in FIG. 1, source electrode S of first field effect transistor 1 which acts as a reference element is at a fixed voltage −U_{SD} and drain electrode D of second field effect transistor 3 which acts as a measuring sensor is at a voltage +U_{SD} which has the same absolute value but is positive. The current through signal line 5 is kept at a constant 0 A by varying voltage U_{Sig} applied to signal line 5. If no substance to be detected is present in the fluid flow, then the channel impedances of first field effect transistor 1 which acts as a reference element and of second field effect transistor 3 which acts as a measuring sensor are identical and the necessary potential of signal line 5 is 0 volt. If second field effect transistor 3 which acts as a measuring sensor is exposed to the at least one substance to be detected, this will result in a change in the channel impedance. Signal voltage U_{Sig} must be varied to maintain a constant current in signal line 5. Therefore, there is a drop in the different voltages across field effect transistors 1, 3, so the different channel impedances are compensated. In the ideal case, external interfering factors produce equal changes in the channel impedance of both second field effect transistor 3 which acts as a measuring sensor and first field effect transistor 1 which acts as a reference element, so these do not influence the resulting signal voltage U_{Sig}. Signal voltage U_{Sig}, which is necessary to keep the current in signal line 5 constant, functions as a measuring signal and in the first order is a function only of the at least one substance to be detected.

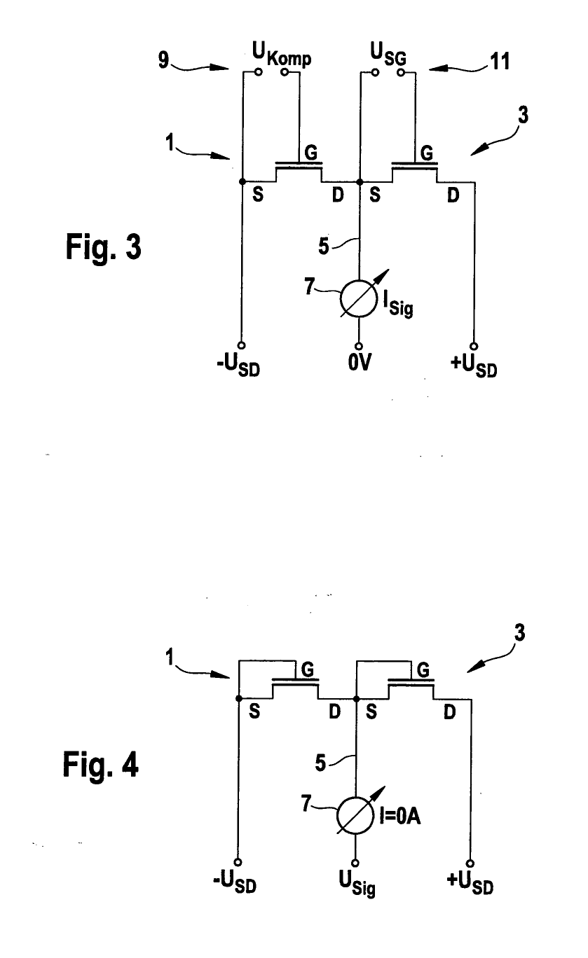

In the specific embodiment illustrated in FIG. 4, in which the current in signal line 5 is kept constant, it is also possible to equalize any differences that may occur between first field effect transistor 1 which acts as a reference element and second field effect transistor 3 which acts as a measuring sensor either by selecting asymmetrical voltages U_{SD}, i.e., the absolute value (of the voltage) applied to source electrode S of first field effect transistor 1 −U_{SD} which acts as a reference element differs from that applied to drain electrode D of second field effect transistor 3 +U_{SD} which acts as a measuring sensor or by selecting a constant current in signal line 5 not equal to zero. In addition, it is also possible to select a different operating point, i.e., a source-gate voltage not equal to zero for each field effect transistor 1, 3. In this way, as shown in FIG. 3, voltage sources 9, 11, using which a voltage different from zero may be applied to the gate electrodes, are connected to gate electrodes G.

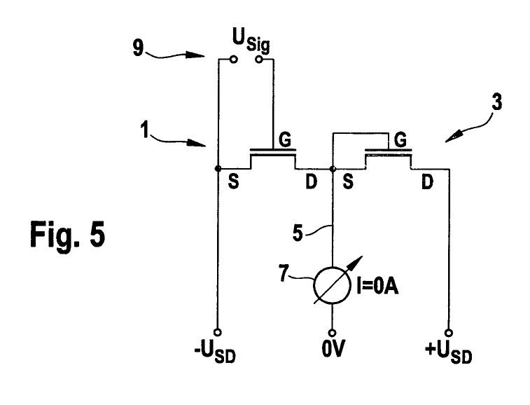

FIG. 5 illustrates an alternative circuit in comparison with the specific embodiment shown in FIG. 2.

Just as in the specific embodiment shown in FIG. 4, the current in signal line 5 is also kept constant in the specific embodiment shown in FIG. 5. At the same time, a potential of 0 volt is applied to signal line 5.

To keep the current in signal line 5 constant, a voltage source 9 is connected to the gate electrode of first field effect transistor 1 which acts as a reference element. The current in signal line 5 is kept constant by varying the voltage on voltage source 9. Signal voltage U_{Sig} is thus picked up at first voltage source 9. This is possible because a change in the source-gate voltage causes a change in the channel impedance of field effect transistor 1 which acts as a reference element. No current flows through signal line 5 if the impedances of the channels of first field effect transistor 1 which acts as a reference element and of second field effect transistor 3 which acts as a measuring sensor are the same. For this reason, the source-gate voltage of field effect transistor 1 which acts as a reference element must produce exactly the same change in the channel impedance in field effect transistor 1 which acts as a reference element as do the substances to be detected on field effect transistor 3, which acts as a measuring sensor, to keep the current constant. Therefore, the required source-gate voltage may be picked up as a measured variable, i.e., as signal voltage U_{Sig} across field effect transistor 1 which acts as a reference element.

In general, interfering factors change the channel impedances of both field effect transistors 1, 3 equally and thus do not cause any change in signal voltage U_{Sig}.

In addition to the specific embodiment shown here, it is also possible for a source-gate voltage not equal to 0 volt to be applied to second field effect transistor 3 which acts as a measuring sensor. However, this produces only a corresponding signal offset in the measuring signal. In addition, it is also possible to operate field effect transistor 1 which acts as a reference element at a constant source-gate voltage, and to control the current in signal line 5 via a variable source-gate voltage across second field effect transistor 3 which acts as a measuring sensor.

1-13. (canceled)

14. An apparatus for detecting at least one substance present in a fluid flow, comprising:
at least one field effect transistor which acts as a measuring sensor; and
at least one field effect transistor which acts as a reference element;
wherein the field effect transistors each have at least one source electrode, one drain electrode and one gate electrode,
wherein the gate electrode of the field effect transistor which acts as a measuring sensor is sensitive to the at least one substance to be detected,
wherein the gate electrode of the field effect transistor which acts as a reference element is essentially insensitive to the at least one substance to be detected, and
wherein the source electrode of one of the field effect transistors and the drain electrode of the other of the field effect transistors are connected to one another and to a signal line.

15. The apparatus of claim 14, wherein the field effect transistor which acts as a reference element and the field effect transistor which acts as a measuring sensor include at least one of a MOSFET, a MISFET, a MESFET, an HEMTs and a suspended gate FET.

16. The apparatus of claim 14, wherein the gate electrode of the field effect transistor which acts as a reference element is connected to a potential terminal of a voltage source.

17. The apparatus of claim 14, wherein the gate electrode of the field effect transistor which acts as a measuring sensor is connected to a potential terminal of a voltage source.

18. The apparatus of claim 14, wherein the gate electrode of the field effect transistor which acts as a reference element is coated with a passivation layer of one of a ceramic, a metal, an organic polymer, and a mixture thereof, which is one of impervious with respect to the at least one substance to be detected and acts as a diffusion barrier.

19. The apparatus of claim 18, wherein the passivation layer has multiple layers of material.

20. The apparatus of claim 14, wherein the gate electrode of the field effect transistor which acts as a reference element has a thick nonporous gate metallization, which is one of impervious to the at least one substance to be detected and acts as a diffusion barrier.

21. The apparatus of claim 14, wherein the gate electrode of the field effect transistor which acts as a reference element is manufactured of a material which is insensitive to the at least one substance to be detected.

22. A method for detecting at least one substance present in a fluid flow, the method comprising:
using a detecting apparatus for detecting the at least one substance present in the fluid flow by performing the following:
applying a constant potential to a signal line of the detecting apparatus; and
measuring a current flowing on the signal line;
wherein the detecting apparatus includes at least one field effect transistor which acts as a measuring sensor, and at least one field effect transistor which acts as a reference element,
wherein the field effect transistors each have at least one source electrode, one drain electrode and one gate electrode,
wherein the gate electrode of the field effect transistor which acts as a measuring sensor is sensitive to the at least one substance to be detected,
wherein the gate electrode of the field effect transistor which acts as a reference element is essentially insensitive to the at least one substance to be detected, and
wherein the source electrode of one of the field effect transistors and the drain electrode of the other of the field effect transistors are connected to one another and to the signal line.

23. The method of claim 22, wherein the voltage source which is connected to the gate electrode of the field effect transistor which acts as a reference element has a compensation voltage.

24. The method of claim 22, wherein the voltage source, which is connected to the gate electrode of the field effect transistor which acts as a measuring sensor, and the voltage source, which is connected to the gate electrode of the field effect transistor which acts as a reference element, has a voltage different from 0 volts.

25. The method of claim 22, wherein the current in the signal line is additionally kept constant by varying the voltage of one of the voltage sources which is connected to the gate electrode of one of the field effect transistors, so that a change in the voltage represents a measuring signal.

26. A method for detecting at least one substance present in a fluid flow, the method comprising:
using a detecting apparatus for detecting the at least one substance present in the fluid flow by performing the following:
keeping constant a current on a signal line of the detecting apparatus; and
measuring a potential of the signal line as the measuring signal which is necessary to maintain a constant current;
wherein the detecting apparatus includes at least one field effect transistor which acts as a measuring sensor, and at least one field effect transistor which acts as a reference element,
wherein the field effect transistors each have at least one source electrode, one drain electrode and one gate electrode,
wherein the gate electrode of the field effect transistor which acts as a measuring sensor is sensitive to the at least one substance to be detected,
wherein the gate electrode of the field effect transistor which acts as a reference element is essentially insensitive to the at least one substance to be detected, and
wherein the source electrode of one of the field effect transistors and the drain electrode of the other of the field effect transistors are connected to one another and to the signal line.

27. The method of claim 22, wherein the voltage source, which is connected to the gate electrode of the field effect transistor which acts as a measuring sensor, and the voltage source, which is connected to the gate electrode of the field effect transistor which acts as a reference element, has a voltage different from 0 volts, and wherein the voltage source, which is connected to the gate electrode of the field effect transistor which acts as a reference element has a compensation voltage.
